(19) United States
(12) Patent Application Publication
(10) Pub. No.: US 2025/0081678 A1
(43) Pub. Date: Mar. 6, 2025

(54) LIGHT-EMITTING DIODE AND LIGHT-EMITTING DEVICE

(71) Applicant: QUANZHOU SANAN SEMICONDUCTOR TECHNOLOGY CO., LTD., Quanzhou (CN)

(72) Inventors: Min HUANG, Quanzhou (CN); Zhibin CHEN, Quanzhou (CN); Xieqing WANG, Quanzhou (CN); Shuo YANG, Quanzhou (CN); Hongbin TANG, Quanzhou (CN); Jipu WU, Quanzhou (CN); Yaowei CHUANG, Quanzhou (CN); Yu-tsai TENG, Quanzhou (CN); Chiawen WU, Quanzhou (CN); Chunping WANG, Quanzhou (CN)

(21) Appl. No.: 18/953,122

(22) Filed: Nov. 20, 2024

Related U.S. Application Data
(63) Continuation of application No. PCT/CN2022/122196, filed on Sep. 28, 2022.

(51) Int. Cl. H01L 33/40; H01L 33/38

(52) U.S. Cl. CPC H10H 20/832; H10H 20/831

(57) ABSTRACT

A LED includes: a semiconductor layer sequence, a first electrode and a second electrode, and the semiconductor layer sequence includes a first semiconductor layer, a light-emitting layer, and a second semiconductor layer arranged sequentially from bottom to top in that order. The first or second electrode includes an electrode structure including a first metal layer, a second metal layer, and a third metal layer. The first metal layer is electrically connected to the semiconductor layer sequence, the second metal layer is disposed on the first metal layer, and the third metal layer is disposed on the second metal layer. The second metal layer includes a nickel-phosphorus alloy or a nickel-phosphorus compound. The design of the second metal layer enhances the electrode adhesion and reliability during soldering, preventing the diffusion of an external solder to the first metal layer, thereby avoiding the risk of electrode detachment caused by push force.

### CROSS-REFERENCE TO RELATED APPLICATION

This application is a continuation of International Patent Application No. PCT/CN2022/122196, filed on Sep. 28, 2022, which is herein incorporated by reference in its entirety.

### TECHNICAL FIELD

The disclosure relates to the field of light-emitting diode (LED) chip technologies, and more particularly to a light-emitting diode and a light-emitting device.

### BACKGROUND

LED is a semiconductor light-emitting element, typically made from a semiconductor such as gallium nitride (GaN), gallium arsenide (GaAs), gallium phosphide (GaP), gallium arsenide phosphide (GaAsP), or aluminum gallium indium phosphide (AlGaInP), etc. The core of the LED is a PN junction with light-emitting properties. Under the forward voltage, electrons from a N region are injected into a P region, and holes from the P region are injected into the N region. A portion of minority carriers that enter the opposite region recombine with majority carriers to emit light. The LED has advantages of high light intensity, high efficiency, small size, and long service life, and is considered one of the most promising light sources currently available.

In the related art, in order to bond with a circuit board through a solder, an electrode structure of the LED generally includes a bonding metal layer (such as a gold layer) as an outermost layer, a nickel layer as a secondary outer layer, and a barrier layer or a metal layer such as a titanium-aluminum structure further towards the electrode interior. During soldering, the gold layer melts and fuses with the solder (usually a tin paste), and the solder diffuses through the gold layer to the nickel layer. Intermetallic compounds (IMCs) are formed by tin and the nickel layer. It is found that when the IMCs are too thick, it is prone to breakage when bonding the electrodes, which is not conducive to the bonding yield.

In summary, the purpose of the disclosure is to provide an electrode structure to improve the bonding yield.

### SUMMARY

In order to solve problems in the related art, the disclosure provides a LED including a semiconductor layer sequence and an electrode structure. The semiconductor layer sequence includes: a first semiconductor layer, a light-emitting layer, and a second semiconductor layer arranged sequentially from bottom to top in that order.

The electrode structure is disposed on the semiconductor layer sequence. The electrode structure includes a first metal layer, a second metal layer, and a third metal layer, the first metal layer is electrically connected to the semiconductor layer sequence, the second metal layer is disposed on the first metal layer, and the third metal layer is disposed on the second metal layer.

The second metal layer includes a nickel-phosphorus alloy or a nickel-phosphorus compound.

In an embodiment, a weight content of phosphorus in the second metal layer is in a range of 0.1% to 5%, or in a range of 5% to 10%.

In an embodiment, a thickness of the second metal layer is in a range of 1000 Ångstrom (Å) to 5000 Å, or in a range of 5000 Å to 10000 Å.

In an embodiment, the first metal layer includes one or more selected from the group consisting of chromium, aluminum, titanium, platinum, and nickel.

In an embodiment, the third metal layer includes one or more selected from the group consisting of tin, gold, platinum and copper.

In an embodiment, a thickness of the third metal layer is in a range of 100 nanometers (nm) to 500 nm.

In an embodiment, the third metal layer includes a first platinum layer, and a thickness of the first platinum layer is in a range of 100 nm to 300 nm.

In an embodiment, the phosphorus in the second metal layer is discontinuously or unevenly distributed in nickel, is distributed in a dotted manner or segmented linear manner.

In an embodiment, nickel in the nickel-phosphorus alloy has a continuous layered structure.

In an embodiment, a second platinum layer is disposed between the first metal layer and the second metal layer, and a thickness of the second platinum layer is in a range of 50 nm to 200 nm.

The disclosure further provides a LED, including:
a semiconductor layer sequence, including: a first semiconductor layer, a light-emitting layer, and a second semiconductor layer arranged sequentially from bottom to top in that order;
a first electrode, electrically connected to the first semiconductor layer; and
a second electrode, electrically connected to the second semiconductor layer.

The first electrode or the second electrode includes an electrode structure, the electrode structure includes a first metal layer, a second metal layer, and a third metal layer. The first metal layer is electrically connected to the semiconductor layer sequence, the second metal layer is disposed on the first metal layer, and the third metal layer is disposed on the second metal layer.

The second metal layer includes a passivation layer including nickel or a nickel alloy, and the passivation layer is configured to inhibit bonding of the second metal layer with an external solder.

In an embodiment, the passivation layer includes a nickel-phosphorus alloy or a nickel-phosphorus compound.

The disclosure further provides a light-emitting device, including: an encapsulated bonding electrode and a LED. The LED includes a semiconductor layer sequence and an electrode structure, and the semiconductor layer sequence is electrically connected to the encapsulated bonding electrode through the electrode structure.

The electrode structure includes a first metal layer, a second metal layer disposed on the first metal layer, and a third metal layer disposed on the second metal layer.

The second metal layer includes a connecting layer and an IMC layer. The connecting layer is connected to the first metal layer. The IMC layer includes a nickel-phosphorus alloy or a nickel-phosphorus compound. The connecting layer includes nickel. A thickness of the IMC layer is in a range of 1 micrometer (μm) to 3 μm, or in a range of 3 μm to 5 μm.

In an embodiment, a weight content of phosphorus in nickel and phosphorus is in a range of 0.1% to 10%.

Compared to the related art, in the LED provided by the disclosure, the electrode structure has the following beneficial effects during soldering due to the nickel-phosphorus alloy in the second metal layer of the electrode structure.

1. During soldering, an external solder diffuses from the third metal layer to the second metal layer of the electrode structure and form IMC with the second metal layer to enhance the adhesion and reliability of a solder joint.

2. The second metal layer can block the diffusion of the external solder to the first metal layer while forming the IMC with the external solder, thereby preventing a decrease in withstanding push force or falling off of electrodes.

3. Due to the role of the phosphorus in the second metal layer, only a part of the second metal layer close to the third metal layer can participate in the formation of the IMC, and the thickness of the IMC is controlled to be within 1 μm to 3 μm, or 3 μm to 5 μm, thereby avoiding the formation of thicker IMC in the electrode structure, and thus improving the bonding yield.

Other features and advantages of the disclosure will be set forth in the subsequent specification, and in part will be apparent from the specification, or may be learned by practice of the disclosure. The purpose and other advantages of the disclosure can be realized and obtained by the structure particularly pointed out in the specification, the claims and the accompanying drawings

### BRIEF DESCRIPTION OF DRAWINGS

To more clearly illustrate the technical solutions of the embodiments or the related art, a brief introduction to the accompanying drawings for the description of the embodiments or the related art is provided below. It is apparent that the accompanying drawings described below are some of the embodiments of the disclosure. For those skilled in the art, without the need for creative effort, other drawings can also be obtained based on these accompanying drawings. In the following description, positional relationships described in the accompanying drawings, unless otherwise specified, are all based on the direction in which components are depicted in the accompanying drawings.

FIG. 1 illustrates a schematic structural diagram of a LED according to an embodiment 1 of the disclosure.

FIG. 2 illustrates a schematic diagram of an electrode structure of the LED according to the embodiment 1 of the disclosure.

FIG. 3 illustrates a schematic diagram of a preferred scheme of the electrode structure of the LED according to the embodiment 1 of the disclosure.

FIG. 4 illustrates a schematic diagram of another preferred scheme of the electrode structure of the LED according to the embodiment 1 of the disclosure.

FIG. 5 illustrates a schematic diagram of an electrode structure of a light-emitting device according to an embodiment 2 of the disclosure.

FIG. 6 illustrates an energy-dispersive X-ray spectroscopy (EDX) diagram of each of nickel, phosphorus and tin in a same area of the second metal layer of the light-emitting device according to the embodiment 2 of the disclosure.

Description of reference numerals: s: 1: LED; 2: light-emitting device; 100: semiconductor layer sequence; 110: first semiconductor layer; 120: light-emitting layer; 130: second semiconductor layer; 140: transparent conductive layer; S1: surface; 200: electrode structure; 201: first electrode; 202: second electrode; 210: first metal layer; 220: second metal layer; 221: connecting layer; 222: IMC layer; 230: third metal layer; 231: first platinum layer; 240: second platinum layer; 300: substrate; 400: encapsulated bonding electrode; 500: external solder; 601: first area tin; 602: second area tin; 603: first area nickel; 604: phosphorus accumulation area; 605: second area nickel; 606: third area nickel.

### DETAILED DESCRIPTION OF EMBODIMENTS

To make the objectives, technical solutions, and advantages of embodiments of the disclosure clearer, a clear and complete description of the technical solutions in the embodiments of the disclosure is provided below in conjunction with the accompanying drawings of the embodiments of the disclosure. Apparently, the described embodiments are only part of the embodiments of the disclosure, not all of them. The technical features designed in the different embodiments of the disclosure described below can be combined with each other as long as they do not conflict with each other. Based on the embodiments of the disclosure, all other embodiments obtained by those skilled in the art without creative labor are within the scope of protection of the disclosure.

In the description of the disclosure, it should be understood that terms such as “center”, “transverse”, “on”, “under”, “left”, “right”, “vertical”, “horizontal”, “top”, “bottom”, “inside”, and “outer” etc., which indicate direction or positional relationships, are based on the direction or positional relationships shown in the accompanying drawings. They are used merely for the purpose of describing the disclosure and simplifying the description, rather than indicating or implying that the devices or components referred to must have a specific orientation or be constructed and operated in a specific orientation. Therefore, they should not be understood as limitations on the disclosure. Furthermore, terms “first” and “second” are used for descriptive purposes and should not be understood as indicating or implying relative importance or specifying the number of the technical features indicated. Thus, features specified as “first” or “second” may explicitly or implicitly include one or more such features. In the description of the disclosure, unless otherwise specified, the term “multiple” means two or more. Additionally, the term “include” and its derivatives mean “include at least”.

In order to make the above features and advantages of the disclosure more obvious and understandable, the following embodiments are presented and described in detail with the accompanying drawings. In the accompanying drawings or descriptions, similar or identical parts are labeled with the same numbers, and in the accompanying drawings, the shape or thickness of the components can be enlarged or reduced. It should be noted that components not shown or described in the accompanying drawings may be in forms known to those skilled in the art.

To achieve at least one of the advantages or other advantages, the disclosure provides a LED, and the LED includes a semiconductor layer sequence 100 and an electrode structure 200.

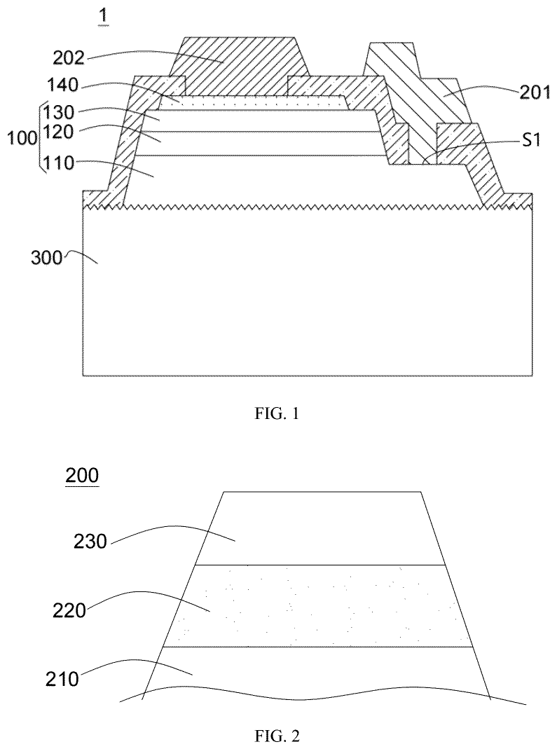

Referring to FIG. 1, FIG. 1 illustrates a schematic structural diagram of the LED 1 according to an embodiment 1 of the disclosure. The LED 1 includes the semiconductor layer sequence 100, and a first electrode 201 disposed on the semiconductor layer sequence 100 and a second electrode 202 disposed on the semiconductor layer sequence 100. However, the concept of the disclosure is not limited to being applied to a flip-chip LED. The semiconductor layer sequence 100 includes a first semiconductor layer 110 with a first polarity, such as an N-type semiconductor layer. The first semiconductor layer 110 is disposed on a substrate 300. The semiconductor layer sequence 100 further includes a light-emitting layer 120 disposed on the first semiconductor layer 110. The light-emitting layer 120 can be a quantum well (QW) structure or a multiple quantum well (MQW) structure. The MQW structure includes MQW layers (Well) and multiple quantum barrier layers (Barrier) alternately disposed in a repetitive manner. The semiconductor layer sequence 100 further includes a second semiconductor layer 130 with a second polarity, such as a P-type semiconductor layer. The second semiconductor layer 130 is disposed on the light-emitting layer 120. The substrate 300 can be made of an insulating transparent material, such as a sapphire substrate and glass, etc.

The first semiconductor layer 110 includes a surface S1 uncovered by the light-emitting layer 120 and the second semiconductor layer 130. The electrode structure 200 includes the first electrode 201 and the second electrode 202. The first electrode 201 is disposed on the surface S1, and the second electrode 202 is disposed on the second semiconductor layer 130.

Materials of the first semiconductor layer 110, the light-emitting layer 120, and the second semiconductor layer 130 include III-V group compound semiconductors, such as GaP, GaAs, or GaN, etc. Additionally, a composition and a thickness of a well layer within the light-emitting layer 120 determine a wavelength of generated light, but the concept of the disclosure is not limited to this. The first semiconductor layer 110, the light-emitting layer 120 and the second semiconductor layer 130 can be manufactured by using epitaxial methods in the related art, such as metal organic chemical vapor deposition (MOCVD). Preferably, in some embodiments, the LED 1 further includes a transparent conductive layer 140 disposed between the second semiconductor layer 130 and the second electrode 202. The transparent conductive layer 140 is configured to expand the current, making the current distribution more uniform and enhancing the light-emitting performance of the LED 1. The transparent conductive layer 140 can be made of a transparent conductive material, and by using a transparent conductive layer 140 of a conductive oxide, the reliability of the LED 1 can be improved. As examples, the transparent conductive material may include one or more selected from the group consisting of indium tin oxide (ITO), indium zinc oxide (IZO), indium oxide (InO), tin oxide (SnO), cadmium tin oxide (CTO), antimony tin oxide (ATO), aluminum zinc oxide (AZO), zinc tin oxide (ZTO), gallium-doped zinc oxide (GZO), tungsten doped indium oxide (IWO), and zinc oxide (ZnO), but the disclosure is not limited to these.

In addition, to address the problems of brittle fracture during a bonding process of the LED 1 due to the formation of thick IMC, resulting in a low bonding yield, the disclosure provides specific structural improvements to the first electrode 201 and the second electrode 202, such as those described in the embodiment 1 above. These improvements are illustrated through the following specific embodiments.

Referring to FIG. 2, FIG. 2 illustrates a schematic diagram of the electrode structure 200 of the first electrode 201 or the second electrode 202 according to the embodiment 1 of the disclosure. An overall structure of the electrode structure 200 can be prepared using a vapor deposition method. The electrode structure 200 includes a first metal layer 210. A bottom of the first metal layer 210 serves as an ohmic contact layer to connect with the semiconductor layer sequence 100 to form an ohmic contact. Preferably, in some embodiments, the electrode structure 200 further includes an adhesive layer disposed under the ohmic contact layer to increase the adhesion between the ohmic contact layer and the semiconductor layer sequence 100. A second metal layer 220 is disposed on the first metal layer 210, and a third metal layer 230 is disposed on the second metal layer 220.

In some embodiments, the first metal layer 210 includes a layered structure made up of one or more selected from the group consisting of chromium, aluminum, titanium, platinum, and nickel to enhance the structural strength of the first metal layer 210. However, the concept of the disclosure is not limited to this. The third metal layer 230 is exemplarily a gold layer with a thickness in a range of 50 nm to 500 nm. The third metal layer 230 serves as the solder at an end of the LED 1 during a soldering process, fusing with the external solder such as solder paste, to form a tin-gold alloy, and tin diffuses into the second metal layer 220 during the fusion process with the third metal layer 230. Preferably, the third metal layer 230 may also include one or more selected from the group consisting of tin, gold, platinum and copper.

In some embodiments, the second metal layer 220 is a nickel-phosphorus alloy or a nickel layer containing phosphorus with a thickness of 1000 Å to 10000 Å formed on the first metal layer 210. The second metal layer 220 may include a nickel-phosphorus compound. A thickness of the second metal layer 220 is preferably in a range of 1000 Å to 5000 Å, and disposed between the third metal layer 230 and the first metal layer 210. If the second metal layer 220 is too thin, the solder joint will be the cold solder joint after soldering, with insufficient strength. If the second metal layer 220 is too thick, due to the loose alloy structure, the hardness increases, while the metal loses its elasticity, the structure becomes brittle, and the stress point during bonding shifts to the inside of the chip, leading to chip structure fracture. Moreover, the second metal layer 220 with an excessive thickness can easily cause electrode falling off. The second metal layer 220 is configured to form an IMC layer containing phosphorus in nickel and tin with the external solder tin that diffuses to a surface of the second metal layer 220, to enhance the adhesion and reliability of the soldering. The nickel-phosphorus alloy is an amorphous structure, without defects such as grain boundaries, dislocations and twinning, etc., and has good corrosion resistance. The nickel-phosphorus alloy can effectively prevent the nickel corrosion caused by the resist remover during metal lift-off after metal evaporating, thereby avoiding the formation of nickel voids after the metal lift-off of the electrode structure 200, and improving the automatic optical inspection (AOI) yield.

In electrode structures in the related art where the nickel is used as a second metal layer, there are still issues related to a thickness of the nickel metal layer. If the nickel metal layer is too thin, the external solder tin paste will diffuse to a first metal layer after reflow soldering, leading to a problem of detachment caused by push force. However, if the nickel metal layer is too thick, due to the high stress of the nickel, it is prone to metal layer detachment on the monitor wafer, making it difficult to monitor the coating thickness and reflectivity. Moreover, the nickel can form a nickel-tin IMC layer thicker than 5 μm with a smaller amount of tin, affecting the bonding yield.

In response to this, the phosphorus in the second metal layer 220 of the disclosure can reduce the amount of the nickel involved in nickel-tin bonding. After reflow soldering, when the nickel-phosphorus alloy reacts with tin, phosphorus atoms accumulate on the nickel surface to form a more protective phosphorus compound passivation film, which prevents further reaction and crystallization of nickel-tin, thereby resulting in the formation of an IMC layer 222 (nickel-phosphorus-tin) with a thickness in a range of 1 μm to 3 μm or 3 μm to 5 μm. Preferably, the phosphorus in the second metal layer 220 is discontinuously or unevenly distributed within the nickel in terms of composition, and can be described as dotted or segmented linear distribution in terms of shape. The metallic nickel forms a continuous layered structure to block the diffusion of the external solder tin to the first metal layer 210. This arrangement ensures that the phosphorus is dispersed within the nickel, avoiding the aggregation of the phosphorus into a continuous layered structure that would completely block the binding of tin with the second metal layer 220, thus preventing a decrease in binding strength after soldering.

In order to further improve the bonding yield of the LED 1, in some embodiments, a weight content of the phosphorus in the nickel-phosphorus alloy of the second metal layer 220 is in a range of 0.1% to 5%, or 5% to 10%. It is preferable to use high-precision EDX mapping testing from Hongkang (Materials Analysis Technology Inc., China) transmission electron microscope (TEM), or secondary ion mass spectroscopy (SIMS) testing, to display the elemental composition ratio in each layer. As shown in FIG. 5, after reflow soldering, the second metal layer 220 forms the IMC layer 222 by reaction of nickel-phosphorus with the external solder, and a portion of the nickel serves as a connecting layer 221 between the first metal layer 210 and the IMC layer 222. The IMC layer 222 also has a blocking effect, which can prevent the detachment of the first metal layer 210. During the formation of the IMC layer 222, due to the aggregation of phosphorus atoms, the weight content of the phosphorus in some areas of the second metal layer 220 is in a range of 10% to 50%. The aggregation of phosphorus can make the structure brittle. If there is too much phosphorus in the second metal layer 220 before soldering, it will lead to rapid phosphorus aggregation that completely blocks the alloy bonding of the external solder with nickel, reducing the soldering adhesion. After reflow soldering or long-term aging, there is a risk of chiplets falling off from the nickel-phosphorus layer. By controlling the weight content of phosphorus in the second metal layer 220, i.e., the nickel-phosphorus alloy or nickel-phosphorus compound, to less than 10% before reflow soldering, the above problems are solved. In some embodiments, a platinum layer can be added to the third metal layer 230 to increase the blocking effect on tin, and the phosphorus content in the second metal layer 220 can be appropriately reduced as the platinum in the third metal layer 230 increases.

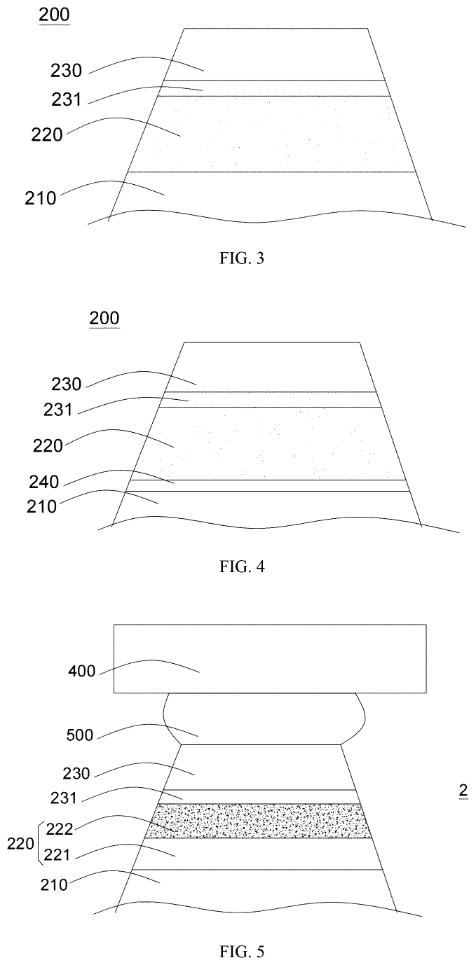

Preferably, in some embodiments, as shown in FIG. 3, the third metal layer 230 further includes a first platinum layer 231 disposed on a side of the third metal layer 230 near the second metal layer 220. A thickness of the first platinum layer 231 can be in a range of 50 nm to 300 nm. Preferably, the thickness of the first platinum layer 231 is not greater than 120 nm. By arranging the first platinum layer 231 within the third metal layer 230 to serve as a barrier, the first platinum layer 231 prevents a part of the tin in the external solder from bonding with the nickel in the second metal layer 220, thereby reducing the thickness of the IMC layer formed. At the same time, the first platinum layer 231 blocks the diffusion of tin to the first metal layer 210, reducing the risk of detachment caused by push force.

Preferably, in a preferred embodiment, as shown in FIG. 4, a second platinum layer 240 is disposed between the first metal layer 210 and the second metal layer 220, and a thickness of the second platinum layer 240 is in a range of 50 nm to 200 nm. The second platinum layer 240 is configured to prevent the diffusion of tin from the external solder into the first metal layer 210, which could cause the electrode to fall off. In some embodiments, the first platinum layer 231 and the second platinum layer 240 can coexist or only one of them can be used.

Additionally, through silicon wafer coating experiments, the stress of nickel is found to be 916 megapascals (MPa), while the stress of platinum is 618 MPa. The structure of this embodiment effectively reduces the stress of the electrode structure 200, thereby reducing the occurrence of abnormalities such as uneven side coating caused by high stress that can lead to the lifting of the adhesive. During AOI control, the electrode structure 200 and the mesa structure can be inspected for contamination and other abnormalities, thereby improving the product's yield.

The disclosure further provides a LED, including: a semiconductor layer sequence 100, a first electrode 201, and a second electrode 202.

The semiconductor layer sequence 100 includes a first semiconductor layer 110, a light-emitting layer 120, and a second semiconductor layer 130 which are arranged sequentially from bottom to top in that order.

The first electrode 201 is electrically connected to the first semiconductor layer 110.

The second electrode 202 is electrically connected to the second semiconductor layer 130.

The first electrode 201 or the second electrode 202 includes an electrode structure 200, the electrode structure 200 includes a first metal layer 210, a second metal layer 220, and a third metal layer 230. The first metal layer 210 is electrically connected to the semiconductor layer sequence 100, the second metal layer 220 is disposed on the first metal layer 210, and the third metal layer 230 is disposed on the second metal layer 220.

The second metal layer 220 includes a passivation layer including nickel or a nickel alloy, and the passivation layer is configured to inhibit bonding of the second metal layer with an external solder. For example, the passivation layer can suppress the eutectic bonding between nickel in the second metal layer 220 and tin in the external solder.

In some embodiments, the passivation layer includes a nickel-phosphorus alloy or a nickel-phosphorus compound.

As shown in FIG. 5, an embodiment 2 of the disclosure further provides a light-emitting device 2. The light-emitting device 2 includes an encapsulated bonding electrode 400 and a LED 1. The LED 1 includes a semiconductor layer sequence 100, a first electrode 201 and a second electrode 202. The first electrode 201 or the second electrode 202 includes an electrode structure 200, and the semiconductor layer sequence 100 is electrically connected to the encapsulated bonding electrode 400 through the first electrode 201 or the second electrode 202. The electrode structure 200 includes a first metal layer 210, a second metal layer 220 and a third metal layer 230. The second metal layer 220 is disposed on the first metal layer 210, and the third metal layer 230 is disposed on the second metal layer 220. The second metal layer 220 includes a connecting layer 221. The second metal layer 220 or the third metal layer 230 further includes an IMC layer 222. The connecting layer 221 is connected to the first metal layer 210. The IMC layer 222 includes a nickel-phosphorus alloy or a nickel-phosphorus compound. The connecting layer 221 includes nickel. A thickness of the IMC layer 222 is in a range of 1 μm to 3 μm, or in a range of 3 μm to 5 μm.

The electrode structure 200 is formed after the electrode structure in the embodiment 1 undergoes reflow soldering with an external solder 500. The external solder 500 can be composed of any suitable material, such as tin, tin-silver alloy, tin-lead alloy, tin-silver-copper alloy, tin-silver-zinc alloy, tin-bismuth-indium alloy, tin-indium alloy, tin-gold alloy, tin-copper alloy, tin-zinc-indium alloy, tin-silver-antimony alloy, or any other appropriate material. The external solder 500 fuses with the original gold solder of the electrode structure 200 to form the third metal layer 230 with a thickness of 100 nm to 100,000 nm that contains gold and tin. At the same time, the external solder 500 diffuses into an original nickel-phosphorus alloy layer of the electrode structure 200 to react to form the IMC layer 222. In some embodiments, the IMC layer 222 contains IMC with nickel, phosphorus, and tin. In some embodiments, the weight content of the phosphorus in the IMC layer 222 ranges from 0.1% to 50%. To avoid brittleness in the electrode structure, it is preferable that the weight content of the phosphorus in the IMC layer 222 ranges from 0.1% to 10%. The phosphorus and nickel refer to the total weight of all phosphorus and nickel in the second metal layer 220. This weight ratio can be determined through high-precision EDX mapping testing with Hongkang TEM, displaying the elemental composition ratio in each layer.

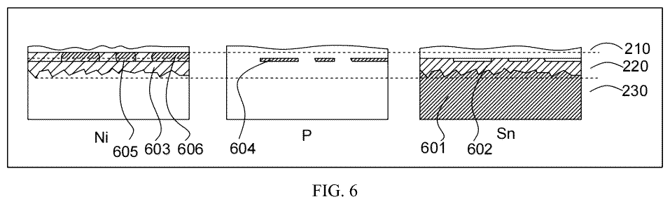

Specifically, as shown in FIG. 6, FIG. 6 shows EDX images of nickel, phosphorus, and tin elements in a same area of the second metal layer 220 in the embodiment 2 of the disclosure. After reflow soldering, the tin from the external solder 500 merges into the third metal layer 230 to form first area tin 601 as shown in FIG. 6. Tin reacts with nickel to form IMC. The tin in the IMC is shown as second area tin 602 in the EDX image of tin, and the nickel in the IMC is shown as the first area nickel 603 in the EDX image of nickel. Phosphorus atoms in the second metal layer 220 are accumulated to form a phosphorus accumulation area 604. The phosphorus accumulation area 604 and a portion of the nickel, i.e., second area nickel 605 overlapping with the phosphorus accumulation area 604, form a nickel-phosphorus layer, inhibiting further reaction between nickel and tin. The inhibition by the nickel-phosphorus layer results in the IMC layer 222 with a uniformly and appropriately thickness in a range of 1-3 μm or 3-5 μm, preventing the formation of thicker IMC and the formation of needle-like IMC as in traditional processes, thereby preventing the electrode structure 200 from peeling off at this interface. Another part of the nickel serves as the connecting layer 221 between the first metal layer 210 and the IMC layer 222, also shown as third area nickel 606 in the EDX image of the nickel, where the aggregated phosphorus also has a blocking effect, preventing tin from diffusing beyond the nickel-phosphorus layer and causing the electrode body to fall off. However, due to the enrichment of the phosphorus atoms and becoming brittle, if the content of phosphorus is too high, an aggregated phosphorus layer will completely block the alloy bonding of the tin and the nickel, and there is a risk of chiplets falling off from the aggregated phosphorus layer after reflow soldering or long-term aging. The above problems are solved by controlling the weight content of phosphorus in the nickel-phosphorus alloy to below 10%. In addition, it is verified that the phosphorus accumulation area 604 is indeed formed by the aggregation of phosphorus atoms, and even if there is phosphorus on the encapsulated bonding electrode 400, the phosphorus will not diffuse into the second metal layer 220.

In summary, in the LED 1 provided by the disclosure, the electrode structure 200 has the following beneficial effects during soldering due to the nickel-phosphorus alloy in the second metal layer 220 of the electrode structure 200. During soldering, the external solder 500 diffuses from the third metal layer 230 to the second metal layer 220 of the electrode structure 200 and form the IMC with the second metal layer 220 to enhance the solder adhesion and reliability. The second metal layer 220 can block the diffusion of the external solder 500 to the first metal layer 210 while forming the IMC with the external solder 500, thereby preventing the electrode from falling off caused by push force. Due to the role of the phosphorus in the second metal layer 220, only a part of the second metal layer 220 close to the third metal layer 230 can participate in the formation of the IMC, and the thickness of the IMC is controlled to be within 1 μm to 3 μm, thereby avoiding the formation of thicker IMC in the electrode structure 200, and thus improving the bonding yield.

Furthermore, those skilled in the art should understand that although there are many problems in the related art, each embodiment or technical solution of the disclosure can be improved in only one or a few aspects, without simultaneously solving all the technical problems listed in the related art or background technology. Those skilled in the art should understand that content not mentioned in a claim should not be used as a limitation on that claim.

Although terms such as semiconductor layer sequence, electrode structure, first metal layer, second metal layer, and third metal layer are frequently used in this article, the possibility of using other terms is not ruled out. The use of these terms is only for the convenience of describing and explaining the essence of the disclosure. Interpreting them as any additional limitations is contrary to the spirit of the disclosure.

What is claimed is:

1. A light-emitting diode (LED), comprising:
a semiconductor layer sequence, comprising: a first semiconductor layer, a light-emitting layer, and a second semiconductor layer arranged sequentially from bottom to top in that order;
a first electrode, electrically connected to the first semiconductor layer; and
a second electrode, electrically connected to the second semiconductor layer;
wherein the first electrode or the second electrode comprises an electrode structure, the electrode structure comprises a first metal layer, a second metal layer, and a third metal layer, the first metal layer is electrically connected to the semiconductor layer sequence, the second metal layer is disposed on the first metal layer, and the third metal layer is disposed on the second metal layer; and
wherein the second metal layer comprises a nickel-phosphorus alloy or a nickel-phosphorus compound.

2. The LED as claimed in claim 1, wherein a weight content of phosphorus in the second metal layer is in a range of 0.1% to 5%, or in a range of 5% to 10%.

3. The LED as claimed in claim 1, wherein a weight content of phosphorus in the second metal layer is in a range of 10% to 50%.

4. The LED as claimed in claim 1, wherein a thickness of the second metal layer is in a range of 1000 Ångstrom (Å) to 5000 Å.

5. The LED as claimed in claim 1, wherein a thickness of the second metal layer is in a range of 5000 Å to 10000 Å.

6. The LED as claimed in claim 1, wherein the first metal layer comprises one or more selected from the group consisting of chromium, aluminum, titanium, platinum, and nickel.

7. The LED as claimed in claim 1, wherein the third metal layer comprises one or more selected from the group consisting of tin, gold, platinum and copper.

8. The LED as claimed in claim 1, wherein a thickness of the third metal layer is in a range of 100 nanometers (nm) to 500 nm.

9. The LED as claimed in claim 1, wherein the third metal layer comprises a platinum layer, and a thickness of the platinum layer is in a range of 50 nm to 300 nm.

10. The LED as claimed in claim 9, wherein the platinum layer is disposed on a side of the third metal layer near the second metal layer, and a thickness of the platinum layer is in a range of 50 nm to 120 nm.

11. The LED as claimed in claim 1, wherein phosphorus in the second metal layer is discontinuously or unevenly distributed in nickel, and is distributed in a dotted or segmented linear manner.

12. The LED as claimed in claim 1, wherein nickel in the nickel-phosphorus alloy has a continuous layered structure.

13. The LED as claimed in claim 1, wherein a platinum layer is disposed between the first metal layer and the second metal layer, and a thickness of the platinum layer is in a range of 50 nm to 200 nm.

14. A LED, comprising:
a semiconductor layer sequence, comprising: a first semiconductor layer, a light-emitting layer, and a second semiconductor layer arranged sequentially from bottom to top in that order;
a first electrode, electrically connected to the first semiconductor layer; and
a second electrode, electrically connected to the second semiconductor layer;
wherein the first electrode or the second electrode comprises an electrode structure, the electrode structure comprises a first metal layer, a second metal layer, and a third metal layer, the first metal layer is electrically connected to the semiconductor layer sequence, the second metal layer is disposed on the first metal layer, and the third metal layer is disposed on the second metal layer; and
wherein the second metal layer comprises a passivation layer comprising nickel or a nickel alloy, and the passivation layer is configured to inhibit bonding of the second metal layer with an external solder.

15. The LED as claimed in claim 14, wherein the passivation layer comprises a nickel-phosphorus alloy or a nickel-phosphorus compound.

16. The LED as claimed in claim 15, wherein a thickness of the second metal layer is in a range of 1000 Å to 5000 Å, and a weight content of phosphorus in the second metal layer is in a range of 0.1% to 10%.

17. A light-emitting device, comprising:
an encapsulated bonding electrode and a LED; wherein the LED comprises a semiconductor layer sequence, a first electrode and a second electrode, and the semiconductor layer sequence is electrically connected to the encapsulated bonding electrode through the first electrode and the second electrode;
wherein the first electrode or the second electrode comprises an electrode structure, the electrode structure comprises:
a first metal layer,
a second metal layer, disposed on the first metal layer, and
a third metal layer, disposed on the second metal layer;
wherein the second metal layer comprises a connecting layer, and the second metal layer or the third metal layer comprises an intermetallic compound (IMC) layer, the connecting layer is connected to the first metal layer, the IMC layer comprises a nickel-phosphorus alloy or a nickel-phosphorus compound, the connecting layer comprises nickel, and a thickness of the IMC layer is in a range of 1 micrometer (μm) to 3 μm, or in a range of 3 μm to 5 μm.

18. The light-emitting device as claimed in claim 17, wherein a weight content of phosphorus in the IMC layer is in a range of 0.1% to 50%.

19. The light-emitting device as claimed in claim 17, wherein a platinum layer is disposed between the third metal layer and the IMC layer, and a thickness of the platinum layer is in a range of 50 nm to 300 nm.

20. The light-emitting device as claimed in claim 17, wherein a platinum layer is disposed between the first metal layer and the second metal layer, and a thickness of the platinum layer is in a range of 50 nm to 200 nm.
